(19) United States
(12) Patent Application Publication
(10) Pub. No.: US 2026/0107367 A1
(43) Pub. Date: Apr. 16, 2026

(54) EUV LIGHT GENERATION APPARATUS AND ELECTRONIC DEVICE MANUFACTURING METHOD

(71) Applicant: Gigaphoton Inc., Tochigi (JP)

(72) Inventor: Atsushi UEDA, Oyama-shi (JP)

(73) Assignee: Gigaphoton Inc., Tochigi (JP)

(21) Appl. No.: 19/321,096

(22) Filed: Sep. 5, 2025

(30) Foreign Application Priority Data
Oct. 15, 2024 (JP) 2024-179767

(51) Int. Cl. H05G 2/00; G03F 7/00

(52) U.S. Cl. CPC H05G 2/003; G03F 7/70033; H05G 2/0082

(57) ABSTRACT

An EUV light generation apparatus includes a chamber in which a target is irradiated with laser light, a light concentrating mirror reflecting EUV light toward an external apparatus, a differential exhaust chamber arranged on an optical path of the EUV light reflected by the light concentrating mirror, a gas supply port through which gas is supplied to a space between the differential exhaust chamber and the light concentrating mirror, a first partition wall having a gas inlet port through which the gas flows into the plasma generation region side from the light concentrating mirror side and through which the EUV light traveling from the plasma generation region toward the light concentrating mirror passes, a gas main exhaust port through which the gas is exhausted, and a constriction member allowing the EUV light to pass therethrough and constrict a gas flow from the gas supply port toward the gas inlet port.

### CROSS-REFERENCE TO RELATED APPLICATIONS

The present application claims the benefit of Japanese Patent Application No. 2024/179767, filed on Oct. 15, 2024, the entire contents of which are hereby incorporated by reference.

### BACKGROUND

### 1. Technical Field

The present disclosure relates to an EUV light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target with laser light has been developed.

### LIST OF DOCUMENTS

### Patent Documents

Patent Document 1: US Patent Application Publication No. 2024/160107

Patent Document 2: International Publication No. WO2011/114958

### SUMMARY

An EUV light generation apparatus according to an aspect of the present disclosure includes a chamber in which a target supplied to a plasma generation region inside thereof is irradiated with laser light to generate EUV light; a light concentrating mirror arranged in the chamber and configured to reflect the EUV light toward an external apparatus; a differential exhaust chamber arranged on an optical path of the EUV light reflected by the light concentrating mirror; a gas supply port through which a gas is supplied to a space between the differential exhaust chamber and the light concentrating mirror; a first partition wall arranged between the plasma generation region and the light concentrating mirror, the first partition wall being provided with a gas inlet port through which the gas supplied through the gas supply port flows into a side of the plasma generation region from a side of the light concentrating mirror and through which the EUV light traveling from the plasma generation region toward the light concentrating mirror passes; a gas main exhaust port through which the gas flowing into the plasma generation region side from the light concentrating mirror side via the gas inlet port is exhausted; and a constriction member arranged between the gas supply port and the light concentrating mirror and configured to allow the EUV light reflected by the light concentrating mirror to pass therethrough and constrict a gas flow from the gas supply port toward the gas inlet port.

An electronic device manufacturing method according to an aspect of the present disclosure includes outputting EUV light generated by an EUV light generation apparatus to an exposure apparatus, and exposing a photosensitive substrate to the EUV light in the exposure apparatus to manufacture an electronic device. Here, the EUV light generation apparatus includes a chamber in which a target supplied to a plasma generation region inside thereof is irradiated with laser light to generate the EUV light; a light concentrating mirror arranged in the chamber and configured to reflect the EUV light toward an external apparatus; a differential exhaust chamber arranged on an optical path of the EUV light reflected by the light concentrating mirror; a gas supply port through which a gas is supplied to a space between the differential exhaust chamber and the light concentrating mirror; a first partition wall arranged between the plasma generation region and the light concentrating mirror, the first partition wall being provided with a gas inlet port through which the gas supplied through the gas supply port flows into a side of the plasma generation region from a side of the light concentrating mirror and through which the EUV light traveling from the plasma generation region toward the light concentrating mirror passes; a gas main exhaust port through which the gas flowing into the plasma generation region side from the light concentrating mirror side via the gas inlet port is exhausted; and a constriction member arranged between the gas supply port and the light concentrating mirror and configured to allow the EUV light reflected by the light concentrating mirror to pass therethrough and constrict a gas flow from the gas supply port toward the gas inlet port.

An electronic device manufacturing method according to an aspect of the present disclosure includes inspecting a defect of a mask by irradiating the mask with EUV light generated by an EUV light generation apparatus, selecting a mask using a result of the inspection, and exposing and transferring a pattern formed on the selected mask onto a photosensitive substrate. Here, the EUV light generation apparatus includes a chamber in which a target supplied to a plasma generation region inside thereof is irradiated with laser light to generate the EUV light; a light concentrating mirror arranged in the chamber and configured to reflect the EUV light toward an external apparatus; a differential exhaust chamber arranged on an optical path of the EUV light reflected by the light concentrating mirror; a gas supply port through which a gas is supplied to a space between the differential exhaust chamber and the light concentrating mirror; a first partition wall arranged between the plasma generation region and the light concentrating mirror, the first partition wall being provided with a gas inlet port through which the gas supplied through the gas supply port flows into a side of the plasma generation region from a side of the light concentrating mirror and through which the EUV light traveling from the plasma generation region toward the light concentrating mirror passes; a gas main exhaust port through which the gas flowing into the plasma generation region side from the light concentrating mirror side via the gas inlet port is exhausted; and a constriction member arranged between the gas supply port and the light concentrating mirror and configured to allow the EUV light reflected by the light concentrating mirror to pass therethrough and constrict a gas flow from the gas supply port toward the gas inlet port.

### BRIEF DESCRIPTION OF THE DRAWINGS

Embodiments of the present disclosure will be described below merely as examples with reference to the accompanying drawings.

FIG. 1 is a schematic view of an EUV light generation apparatus according to a comparative example as viewed in the horizontal direction.

FIG. 2 is a schematic view of the EUV light generation apparatus according to the comparative example as viewed in the vertical direction.

FIG. 3 is a view schematically showing the configuration of a chamber of the EUV light generation apparatus according to the comparative example.

FIG. 4 is a view schematically showing the configuration of the EUV light generation apparatus according to a first embodiment.

FIG. 5 is a view schematically showing the configuration of the chamber of the EUV light generation apparatus according to the first embodiment.

FIG. 6 is a view schematically showing the configuration of the chamber of the EUV light generation apparatus according to a modification of the first embodiment.

FIG. 7 is a view showing a modification of a cylindrical structure.

FIG. 8 is a view schematically showing the configuration of the chamber of the EUV light generation apparatus according to a second modification of the first embodiment.

FIG. 9 is a sectional view of a block taken along line A-A of FIG. 8.

FIG. 10 is a view schematically showing the configuration of the EUV light generation apparatus according to a second embodiment.

FIG. 11 is a view schematically showing the configuration of the EUV light generation apparatus according to a first modification of the second embodiment.

FIG. 12 is a view schematically showing the configuration of the EUV light generation apparatus according to a second modification of the second embodiment.

FIG. 13 is a diagram schematically showing the configuration of an exposure apparatus.

FIG. 14 is a diagram schematically showing the configuration of an inspection apparatus.

### DESCRIPTION OF EMBODIMENTS

### <Contents>

### 1. Comparative Example

1.1 Configuration
1.2 Operation
1.3 Problem

### 2. First Embodiment

2.1 Configuration
2.2 Operation
2.3 Effect
2.4 Modification
   2.4.1 First modification
   2.4.2 Second modification
      3. Second embodiment
3.1 Configuration
3.2 Operation
3.3 Effect
3.4 Modification
   3.4.1 First modification
   3.4.2 Second modification

### 4. Electronic Device Manufacturing Method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration

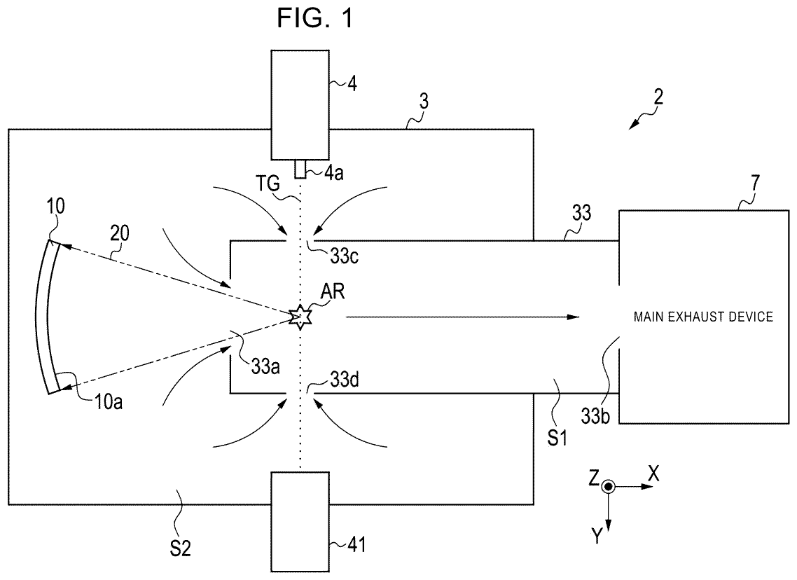

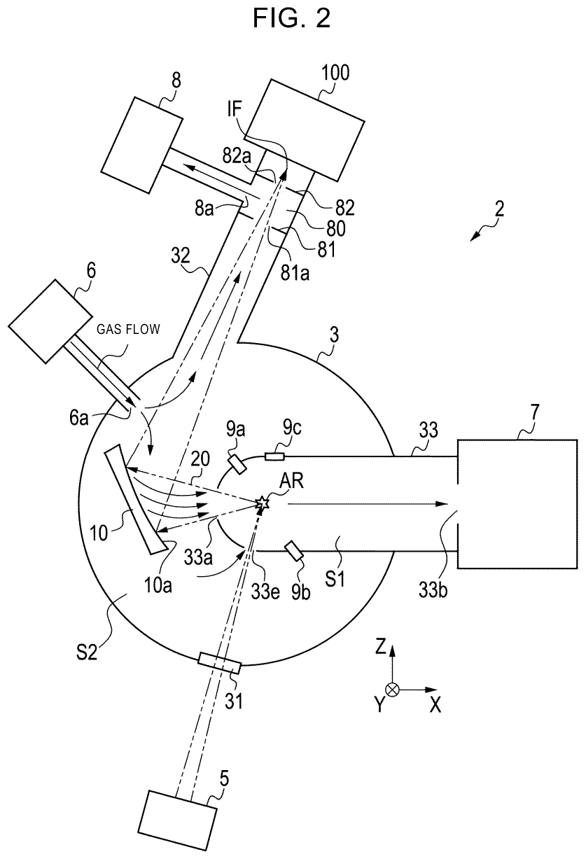

FIGS. 1 and 2 schematically show the configuration of an EUV light generation apparatus 2 according to a comparative example. FIG. 1 is a schematic view of the EUV light generation apparatus 2 as viewed in the horizontal direction. FIG. 2 is a schematic view of the EUV light generation apparatus 2 as viewed in the vertical direction.

The EUV light generation apparatus 2 includes a chamber 3, a target supply device 4, and a laser device 5. The chamber 3 is a sealable container. The target supply device 4 supplies a droplet-shaped target TG into the chamber 3. The target TG is liquid tin. The target supply device 4 outputs the target TG from a nozzle 4a at a constant cycle toward a plasma generation region AR located vertically below the nozzle 4a. The diameter of the target TG is 10 to 30μm.

A window 31 for causing pulse laser light output from the laser device 5 arranged outside the chamber 3 to enter the inside thereof is formed at the chamber 3. The pulse laser light transmitted through the window 31 is radiated to the target TG in the plasma generation region AR. The pulse laser light is an example of the “laser light” according to the technology of the present disclosure.

The chamber 3 is connected with a connection pipe 32 for providing communication between the inside of the chamber 3 and the inside of an external apparatus 100. The external apparatus 100 is an exposure apparatus 100a or an inspection apparatus 100b.

Further, a gas supply port 6a is formed at the chamber 3. A gas supply device 6 is connected to the gas supply port 6a. The gas supply device 6 includes a gas tank and supplies a gas to a space between a later-described differential exhaust chamber 80 and a light concentrating mirror 10.

The gas to be supplied by the gas supply device 6 includes, for example, a hydrogen gas. The gas may be a hydrogen gas having a hydrogen concentration of 100%. The gas may be a balance gas having a hydrogen gas concentration of about 3%. In this case, the balance gas includes, for example, a nitrogen (N₂) gas or an argon (Ar) gas. Further, the gas supply device 6 may be provided with a flow rate adjustment valve capable of adjusting the flow rate of the gas.

A target collection device 41 is provided in the chamber 3 at a position facing the target supply device 4. The target collection device 41 is a drain tank that collects unnecessary target TG not having contributed to the generation of the EUV light 20 in the plasma generation region AR.

Further, in the chamber 3, a partition wall 33 is provided between the plasma generation region AR and the light concentrating mirror 10. For example, the partition wall 33 has a cylindrical shape extending from the inside to the outside of the chamber 3, and surrounds the plasma generation region AR. The partition wall 33 is formed of stainless steel, aluminum, or the like. For example, the partition wall 33 includes a cylindrical portion having an inner diameter of 160 mm. The partition wall 33 is also referred to as a debris shield. The partition wall 33 is an example of the “first partition wall” according to the technology of the present disclosure.

Among two opposite end portions of the partition wall 33, a gas inlet port 33a is formed at an end portion located in the internal space, and a gas main exhaust port 33b is formed at an end portion located in the external space. The gas main exhaust port 33b is connected to a main exhaust device 7 including an exhaust pump. The main exhaust device 7 exhausts the gas supplied from the gas supply device 6 into the chamber 3 and flowing into the internal space in the partition wall 33. The gas inlet port 33a has an elliptical shape or a circular shape.

A target introduction port 33c and a target discharge port 33d are formed at the partition wall 33. The target introduction port 33c and the target discharge port 33d are arranged so as to face each other on the trajectory of the target TG.

A laser entrance port 33e is formed at the partition wall 33. The laser entrance port 33e is arranged on the optical path of the pulse laser light that transmits through the window 31 and enters the chamber 3.

Further, the partition wall 33 is provided with sensors 9a, 9b for monitoring the state of the plasma generation region AR or the vicinity thereof. For example, the sensor 9a is a target sensor that detects at least one of the presence, trajectory, position, and velocity of the target TG. For example, the sensor 9b is a sensor that monitors a light emission point of the EUV light 20.

Further, the partition wall 33 is provided with a laser damper 9c on the opposite side of the laser entrance port 33e with respect to the plasma generation region AR. The pulse laser light entering from the laser entrance port 33e and not radiated to the target TG is incident on the laser damper 9c. The laser damper 9c converts the incident pulse laser light into heat.

Hereinafter, the internal space of the partition wall 33 is referred to as a first space S1, and the space outside the partition wall 33 and inside the chamber 3 is referred to as a second space S2. The plasma generation region AR is located in the first space S1. The connection pipe 32 communicates with the second space S2. The gas inlet port 33a, the target introduction port 33c, the target discharge port 33d, and the laser entrance port 33e are formed between the first space S1 and the second space S2.

The light concentrating mirror 10 includes a reflection surface 10a which is a part of a spheroidal surface, and is arranged in the second space S2. A multilayer reflective film in which molybdenum and silicon are alternately laminated is formed on the reflection surface 10a. The light concentrating mirror 10 is arranged such that a first focal point of the spheroidal surface is located in the plasma generation region AR and a second focal point thereof is located at an intermediate focal point IF. The intermediate focal point IF is located in the connection pipe 32.

A part of the EUV light 20 emitted from the plasma generated by irradiating the target TG with the pulse laser light in the plasma generation region AR passes through the gas inlet port 33a from the first space S1 and is incident on the light concentrating mirror 10 arranged in the second space S2. The light concentrating mirror 10 reflects the EUV light 20 incident thereon toward the external apparatus 100 located in a direction different from the incident direction.

The gas supply port 6a described above communicates with the second space S2, and is arranged so that the gas flowing into the second space S2 flows to the reflection surface 10a of the light concentrating mirror 10. The gas flow rate flowing from the gas supply port 6a into the second space S2 is preferably within the range of 20 to 60 NLM (normal liter/min).

The laser device 5 is arranged such that the output pulse laser light enters the second space S2 in the chamber 3 through the window 31 and enters the plasma generation region AR through the laser entrance port 33e.

The laser device 5 outputs prepulse laser (PPL) light and main pulse laser (MPL) light as the pulse laser light. Specifically, the laser device 5 includes a PPL device (not shown) that outputs PPL light, and a MPL device (not shown) that outputs MPL light. For example, the PPL device is an Nd: YAG laser device, and the MPL device is an Nd: YAG laser device or₂ a CO₂ laser device. For example, a wavelength of the PPL light is equal to a wavelength of the MPL light, and is 1.06 μm. The laser device 5 outputs the PPL light and the MPL light in this order.

The connection pipe 32 is provided with the differential exhaust chamber 80 on the optical path of the EUV light 20. The differential exhaust chamber 80 is arranged in the vicinity of the intermediate focal point IF. The differential exhaust chamber 80 is a space sandwiched between two orifice plates 81, 82 arranged to partition the connection pipe 32. The orifice plates 81, 82 each have an orifice 81a, 82a arranged on the optical path of the EUV light 20. For example, each of the orifices 81a, 82a has a circular shape. The orifice plate 81 corresponds to the “first orifice plate” according to the technology of the present disclosure. The orifice plate 82 corresponds to the “second orifice plate” according to the technology of the present disclosure. The orifice 81a corresponds to the “first orifice” according to the technology of the present disclosure. The orifice 82a corresponds to the “second orifice” according to the technology of the present disclosure.

The orifices 81a, 82a are arranged at positions through which the EUV light 20 reflected by the light concentrating mirror 10 passes. Further, the orifice 82a is arranged closer to the external apparatus 100 than the orifice 81a. The diameter of the orifice 81a is preferably larger than the diameter of the orifice 82a. Further, the intermediate focal point IF may be located in the orifice 82a of the orifice plate 82.

A gas exhaust port 8a is formed in a region of the connection pipe 32 in which the differential exhaust chamber 80 is provided. That is, the gas exhaust port 8a is in communication with the differential exhaust chamber 80. The gas exhaust port 8a is connected to an exhaust device 8 including an exhaust pump. The exhaust device 8 maintains the differential exhaust chamber 80 at a pressure lower than the inside of the chamber 3 by exhausting the differential exhaust chamber 80.

The inside of the external apparatus 100 is exhausted by an exhaust device (not shown). For example, the pressure in the chamber 3 is several tens of Pa, and the pressure in the external apparatus 100 is less than several Pa.

In FIGS. 1 and 2, an X direction is a direction from the plasma generation region AR toward the main exhaust device 7, a Y direction is the vertical direction, and a Z direction is a direction orthogonal to the X direction and the Y direction. In the comparative example, the X direction, the Y direction, and the Z direction are orthogonal to each other, but are not necessarily orthogonal to each other.

### 1.2 Operation

The operation of the EUV light generation apparatus 2 according to the comparative example will be described. First, the target supply device 4 outputs the target TG from the nozzle 4a at a constant cycle. The output target TG travels toward the plasma generation region AR as passing through the target introduction port 33c. The laser device 5 irradiates the target TG supplied to the plasma generation region AR at the constant cycle with the pulse laser light at a constant cycle to generate the EUV light 20. The timing at which the pulse laser light is output from the laser device 5 is determined based on a passage timing of the target TG from the sensor 9a.

The EUV light 20 generated in the plasma generation region AR and traveling toward the light concentrating mirror 10 passes through the gas inlet port 33a and is reflected by the light concentrating mirror 10 toward the external apparatus 100. The EUV light 20 reflected by the light concentrating mirror 10 passes through the orifices 81a, 82a in the connection pipe 32 and enters the external apparatus 100. In the external apparatus 100, a predetermined process is performed using the EUV light 20.

The gas supplied into the second space S2 in the chamber 3 through the gas supply port 6a mainly flows toward the light concentrating mirror 10 and then flows into the first space S1 through the gas inlet port 33a, the target introduction port 33c, the target discharge port 33d, and the laser entrance port 33e. The gas flowing into the first space S1 passes through the gas main exhaust port 33b and is exhausted by the main exhaust device 7. As the gas flows from the second space S2 to the first space S1 in this manner, debris generated in the plasma generation region AR is suppressed from diffusing toward the second space S2 where the light concentrating mirror 10 is arranged. The debris is residual mist in which a part of the target TG remains without being turned into plasma by irradiation with the pulse laser light. For example, the residual mist is a minute particle of liquid tin or the like.

Further, a part of the debris may adhere to the reflection surface 10a of the light concentrating mirror 10. The adhering objects on the reflection surface 10a react with radicals generated by the gas in the second space S2 being excited by the EUV light 20 to become volatile substances. This radical is, for example, a hydrogen radical. Thus, the reflection surface 10a is cleaned by volatilization of the adhering objects.

### 1.3 Problem

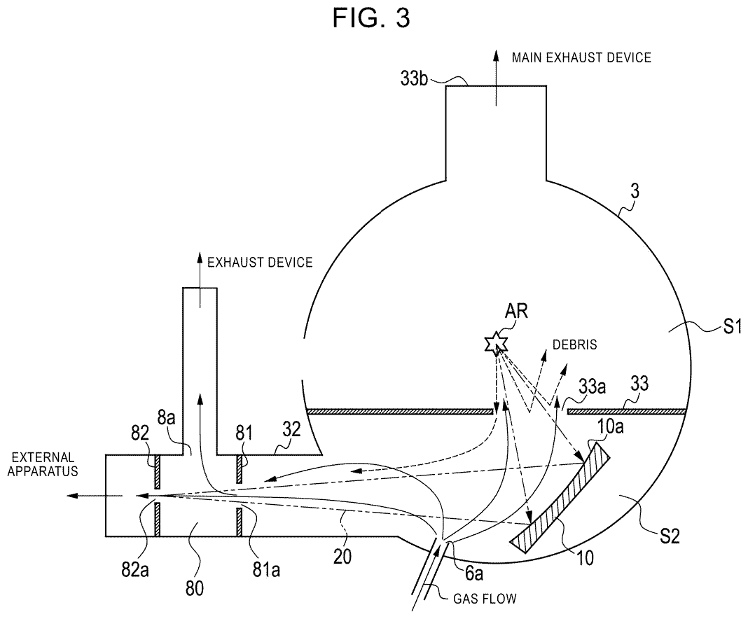

FIG. 3 schematically shows the configuration of the chamber 3 of the EUV light generation apparatus according to the comparative example. In FIG. 3, the partition wall 33 is schematically shown as having a flat plate shape.

As shown in FIG. 3, the gas supplied into the second space S2 through the gas supply port 6a branches and flows in the direction toward the connection pipe 32 in addition to the direction toward the first space S1. A part of the gas flows into the connection pipe 32 toward the external apparatus 100, and flows into the differential exhaust chamber 80 through the orifice 81a. Since the differential exhaust chamber 80 is provided to reduce the inflow of gas to the external apparatus 100, most of the gas flowing into the differential exhaust chamber 80 is exhausted through the gas exhaust port 8a. A part of the gas flowing into the differential exhaust chamber 80 flows into the external apparatus 100 through the orifice 82a.

Most of the debris generated in the plasma generation region AR is exhausted by the main exhaust device 7 together with the gas flowing into the first space S1 from the second space S2 through the gas inlet port 33a. However, a small amount of debris may enter the second space S2 through the gas inlet port 33a. Since the gas supplied from the gas supply port 6a to the second space S2 is dispersed and exhausted in a plurality of directions, debris entering the second space S2 may diffuse and enter the external apparatus 100 through the orifices 81a, 82a together with a part of the gas. When debris containing tin or the like enters the external apparatus 100, elements configuring the EUV optical system inside thereof are contaminated, and the optical performance deteriorates. When the optical performance deteriorates, maintenance or the like may be required.

An object of the present disclosure is to suppress adhesion of debris to the light concentrating mirror 10 and to suppress entering of debris into the external apparatus 100.

### 2. First Embodiment

### 2.1 Configuration

The configuration of the EUV light generation apparatus 2 according to a first embodiment of the present disclosure is similar to that of the EUV light generation apparatus 2 according to the comparative example except that the configuration of the chamber 3 is different.

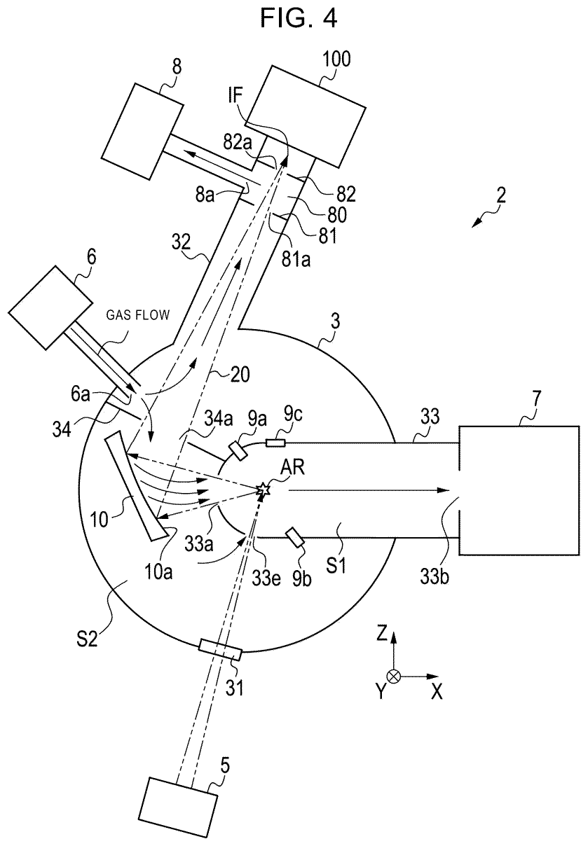

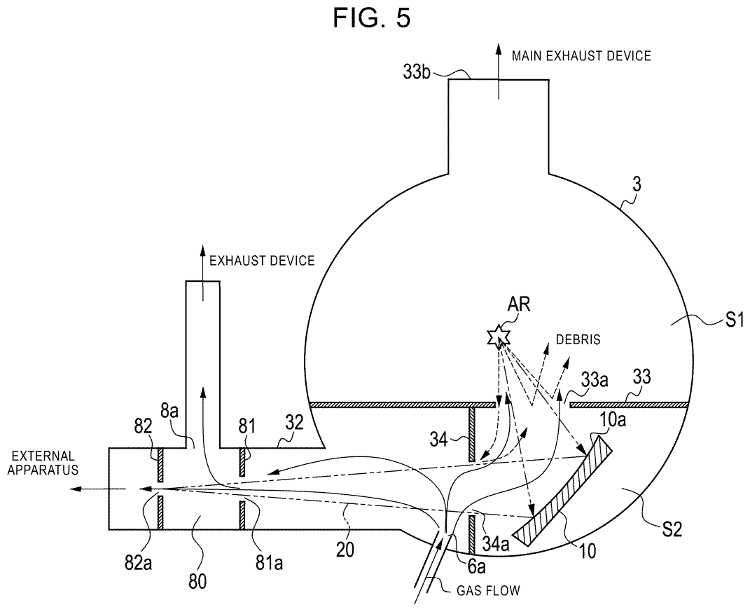

FIG. 4 schematically shows the configuration of the EUV light generation apparatus 2 according to the first embodiment. FIG. 5 schematically shows the configuration of the chamber 3 of the EUV light generation apparatus 2 according to the first embodiment. In the present embodiment, in the second space S2, a flat-plate-shaped partition wall 34 is provided between the gas supply port 6a and the light concentrating mirror 10. The partition wall 34 is arranged so as to intersect the optical path of the EUV light 20 reflected by the light concentrating mirror 10, and partitions the second space S2 into a region on the side of the light concentrating mirror 10 and a region on the side toward the external apparatus 100. The partition wall 34 is an example of the “second partition wall”according to the technology of the present disclosure.

The partition wall 34 includes an opening 34a, and is arranged so that the EUV light 20 reflected by the light concentrating mirror 10 passes through the opening 34a. The shape of the opening 34a is preferably similar to the cross-sectional shape of the EUV light 20 at the position of the partition wall 34. For example, the opening 34a has an elliptical shape or a circular shape.

The size of the opening 34a is preferably larger than the size of the cross section of the EUV light 20 at the position of the partition wall 34. When the diameter of the gas inlet port 33a is D1, the diameter of the opening 34a is D2, the diameter of the orifice 81a is D3, and the diameter of the orifice 82a is D4, Expression (1) or (2) described below is preferably satisfied. Here, the diameter refers to a diameter of a circle or a major diameter of an ellipse.

D2≥D1>D3>D4 (1)

D1≥D2>D3>D4 (2)

The gas flowing into the chamber 3 through the gas supply port 6a mainly flows through the opening 34a of the partition wall 34 toward the gas inlet port 33a. Therefore, the gas flow from the gas supply port 6a toward the gas inlet port 33a is constricted by the opening 34a. Here, constriction means that the flow path of the gas is partially narrowed or diffusion of the gas is partially suppressed. The partition wall 34 is an example of the “constriction member that constricts a gas flow”according to the technology of the present disclosure.

The partition wall 34 is preferably arranged between the gas supply port 6a and the light concentrating mirror 10 on a side closer to the gas supply port 6a than to the light concentrating mirror 10. Further, the partition wall 34 may be arranged between the differential exhaust chamber 80 and the light concentrating mirror 10 on a side closer to the differential exhaust chamber 80 than to the light concentrating mirror 10. For this purpose, the gas supply port 6a is required to be arranged closer to the differential exhaust chamber 80 than to the light concentrating mirror 10. The gas supply port 6a may be arranged in the connection pipe 32.

### 2.2 Operation

The operation of the EUV light generation apparatus 2 according to the present embodiment is similar to that of the comparative embodiment except for the flow of the gas in the chamber 3. In the present embodiment, the gas supplied to the second space S2 in the chamber 3 through the gas supply port 6a mainly flows toward the gas inlet port 33a, but this gas flow is rectified by being constricted at the opening 34a of the partition wall 34 and flows toward the light concentrating mirror 10. That is, the gas flowing through the opening 34a flows toward the light concentrating mirror 10 at many positions in the cross section along the opening 34a. Accordingly, the flow rate of the gas is improved as compared with the case in which the partition wall 34 is not provided as in the comparative example.

### 2.3 Effect

In the present embodiment as well, some debris generated in the plasma generation region AR may enter the second space S2 through the gas inlet port 33a. However, in the present embodiment, since the gas passing through the opening 34a of the partition wall 34 is rectified and the flow velocity is improved, the entering and diffusion of debris from the opening 34a toward the external apparatus 100 are suppressed. Accordingly, entering of debris into the external apparatus 100 is suppressed. Therefore, according to the present embodiment, it is possible to suppress adhesion of debris to the light concentrating mirror 10 by the partition wall 33 as a debris shield, and it is possible to suppress entering of debris into the external apparatus 100 by the partition wall 34 as the constriction member.

Accordingly, deterioration of the optical performance of the external apparatus 100 due to debris is suppressed, and the frequency of maintenance and the like is decreased.

### 2.4 Modification

Next, various modifications of the first embodiment will be described. First and second modifications described below are different from the first embodiment only in the configuration of the constriction member and the arrangement of the gas supply port 6a.

### 2.4.1 First Modification

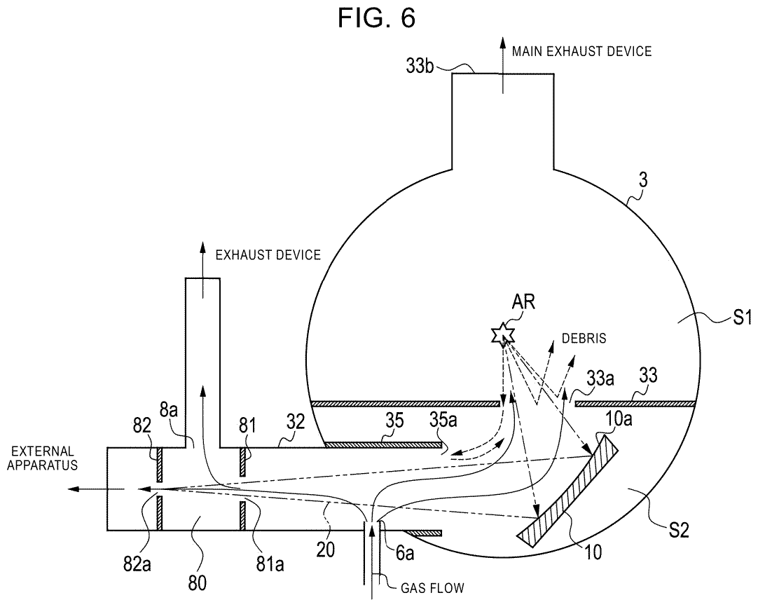

FIG. 6 schematically shows the configuration of the chamber 3 of the EUV light generation apparatus 2 according to the first modification of the first embodiment. In the present modification, a cylindrical structure 35 is provided instead of the partition wall 34. Further, in the present modification, the gas supply port 6a is arranged in the connection pipe 32.

The cylindrical structure 35 is arranged between the gas supply port 6a and the light concentrating mirror 10 so that the EUV light 20 reflected by the light concentrating mirror 10 passes through the inside thereof. Specifically, the cylindrical structure 35 is connected to an end portion of the connection pipe 32. Here, the cylindrical structure 35 may be integrally formed with the connection pipe 32.

The shape of the opening 35a located at the end portion of the cylindrical structure 35 on the light concentrating mirror 10 side is preferably similar to the cross-sectional shape of the EUV light 20 at the position of the opening 35a. For example, the opening 35a has an elliptical shape or a circular shape. That is, the cylindrical structure 35 has an elliptical cylindrical shape or a cylindrical shape. In the present modification, the cross-sectional area of the internal space of the cylindrical structure 35 is constant along the optical path of the EUV light 20. Here, the cross-sectional area refers to an area of a plane obtained by cutting the internal space in a direction perpendicular to the optical path of the EUV light 20.

The size of the opening 35a is preferably larger than the size of the cross section of the EUV light 20 at the position of the opening 35a. When the diameter of the gas inlet port 33a is D1, the diameter of the opening 35a is D2, the diameter of the orifice 81a is D3, and the diameter of the orifice 82a is D4, Expression (1) or (2) described above is preferably satisfied.

The gas supply port 6a is arranged at a position through which the gas is supplied to the internal space of the cylindrical structure 35. The gas supplied from the gas supply port 6a to the inner space of the cylindrical structure 35 mainly flows through the opening 35a toward the gas inlet port 33a. Therefore, the gas flow from the gas supply port 6a toward the gas main exhaust port 33b is constricted by the cylindrical structure 35. The cylindrical structure 35 is an example of the “constriction member that constricts a gas flow” according to the technology of the present disclosure.

In the present modification as well, similarly to the embodiment described above, since the gas passing through the cylindrical structure 35 is rectified and the flow velocity is improved, the entering and diffusion of debris from the opening 35a toward the external apparatus 100 is suppressed. Accordingly, entering of debris into the external apparatus 100 is suppressed. Therefore, according to the present modification, it is possible to suppress adhesion of debris to the light concentrating mirror 10 by the partition wall 33 as a debris shield, and it is possible to suppress entering of debris into the external apparatus 100 by the cylindrical structure 35 as the constriction member.

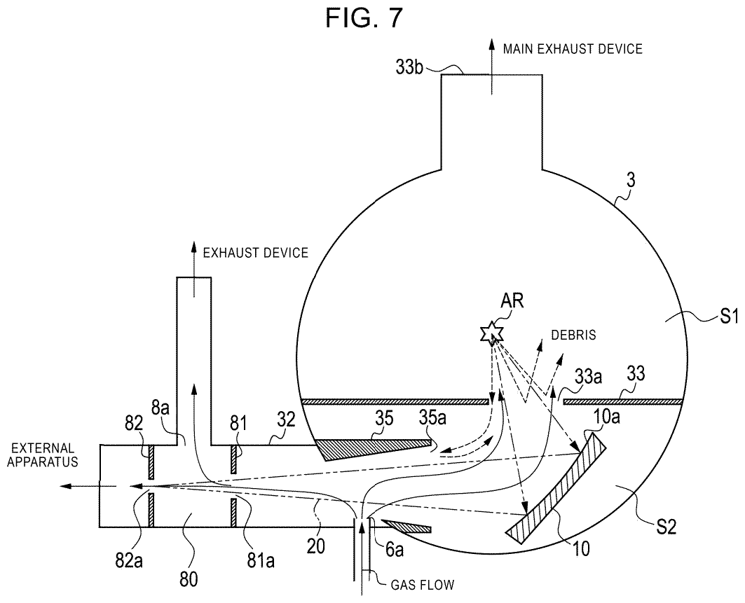

Here, although the cross-sectional area of the cylindrical structure 35 is constant in the present modification, as shown in FIG. 7, the cylindrical structure 35 may be configured such that the cross-sectional area of the internal space decreases along the travel direction of the EUV light 20.

### 2.4.2 Second Modification

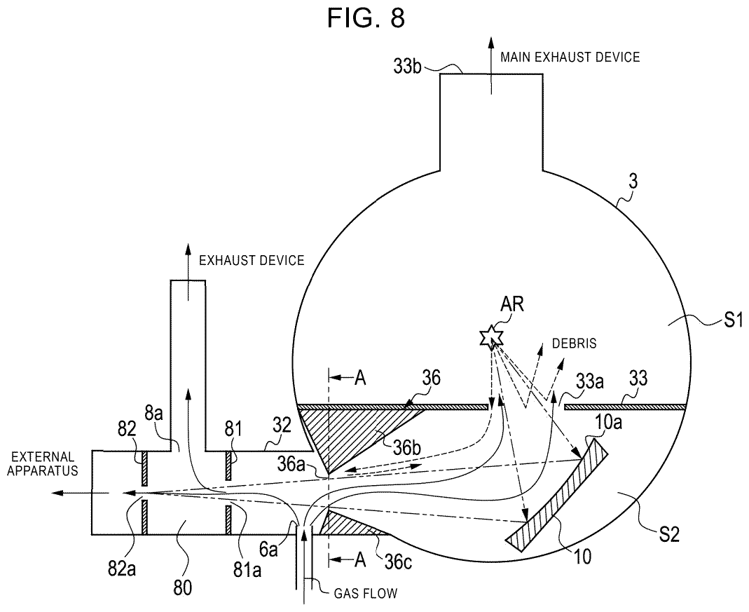

FIG. 8 schematically shows the configuration of the chamber 3 of the EUV light generation apparatus 2 according to the second modification of the first embodiment. In the present modification, a block 36 is provided instead of the partition wall 34. Further, in the present modification, the gas supply port 6a is arranged in the connection pipe 32.

The block 36 includes an opening through which the EUV light reflected by the light concentrating mirror 10 passes, and which surrounds the optical path of the EUV light 20. Specifically, the block 36 includes an inclined surface that is tapered toward the differential exhaust chamber 80, and the cross-sectional area of the space surrounded by this surface decreases as approaching the differential exhaust chamber 80. The block 36 may have a sheet metal structure or may be made by shaving or casting. Further, the block 36 may be integrally formed with the chamber 3.

In the present modification, the block 36 is configured of a plurality of members. Specifically, the block 36 is configured of a first member 36b and a second member 36c. The first member 36b is fixed to the partition wall 33. The second member 36c is fixed to the chamber 3.

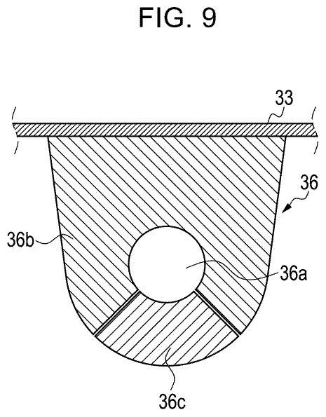

FIG. 9 shows a cross-section of the block 36 along line A-A of FIG. 8. Although the first member 36b and the second member 36c may be connected to each other, a gap may exist between the first member 36b and the second member 36c. In the example shown in FIG. 9, the opening 36a is circular, but the opening 36a may be elliptical.

The size of the opening 36a is preferably larger than the size of the cross section of the EUV light 20 at the position of the opening 36a. When the diameter of the gas inlet port 33a is D1, the diameter of the opening 36a is D2, the diameter of the orifice 81a is D3, and the diameter of the orifice 82a is D4, Expression (1) or (2) described above is preferably satisfied.

The gas flowing into the chamber 3 through the gas supply port 6a mainly flows through the opening 36a of the block 36 toward the gas inlet port 33a. Therefore, the gas flow from the gas supply port 6a toward the gas main exhaust port 33b is constricted by the opening 36a of the block 36. The block 36 is an example of the “constriction member that constricts a gas flow”according to the technology of the present disclosure.

In the present modification as well, similarly to the embodiment described above, since the gas passing through the opening 36a of the block 36 is rectified and the flow velocity is improved, the entering and diffusion of debris from the opening 36a toward the external apparatus 100 is suppressed. Accordingly, entering of debris into the external apparatus 100 is suppressed. Therefore, according to the present modification, it is possible to suppress adhesion of debris to the light concentrating mirror 10 by the partition wall 33 as a debris shield, and it is possible to suppress entering of debris into the external apparatus 100 by the block 36 as the constriction member.

### 3. Second Embodiment

Next, a second embodiment of the present disclosure will be described. The configuration of the EUV light generation apparatus 2 according to the second embodiment of the present disclosure is similar to that of the EUV light generation apparatus 2 according to the first embodiment except that the configuration of the chamber 3 is different.

### 3.1 Configuration

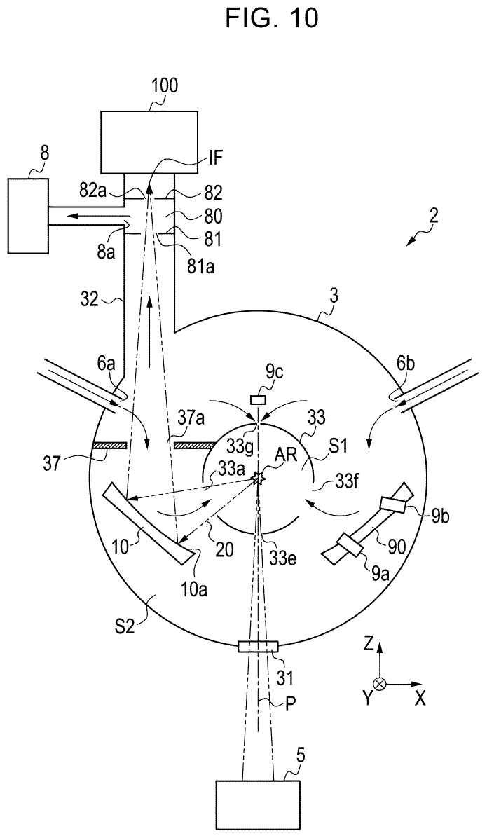

FIG. 10 schematically shows the configuration of the EUV light generation apparatus 2 according to the second embodiment. In the present embodiment, two gas supply ports 6a, 6b are formed in the chamber 3. The gas supply ports 6a, 6b are connected to the gas supply device 6, and supply the gas to the second space S2 in the chamber 3. Here, in FIG. 10, the gas supply device 6 is not shown. The gas supply ports 6a, 6b are respectively formed at symmetrical positions with respect to a plane P including the optical axis of the pulse laser light output from the laser device 5. In the present embodiment, the optical axis of the pulse laser light is parallel to the Z direction, and the plane P is a plane parallel to the ZY plane.

In the present embodiment, the partition wall 33 surrounding the plasma generation region AR is a cylindrical shape extending in the Y direction. In the present embodiment, the gas main exhaust port 33b is formed at an end potion of the partition wall 33 in the extending direction, and the main exhaust device 7 is connected to the gas main exhaust port 33b. In FIG. 10, the gas main exhaust port 33b and the main exhaust device 7 are not shown. The shape of the partition wall 33 is symmetrical with respect to the plane P.

In the present embodiment, two gas inlet ports 33a, 33f are formed in the partition wall 33. The gas inlet ports 33a, 33f are formed at symmetrical positions with respect to the plane P. A part of the gas supplied through the gas supply ports 6a, 6b to the second space S2 flows into the first space S1 through the gas inlet ports 33a, 33f.

Further, the partition wall 33 is provided with a laser exit port 33g on the optical axis of the pulse laser light in addition to the laser entrance port 33e. The pulse laser light entering from the laser entrance port 33e and not radiated to the target TG passes through the laser exit port 33g. The laser damper 9c is arranged at a position where the pulse laser light having passed through the laser exit port 33g enters.

Further, in the present embodiment, an auxiliary plate 90 is provided in the second space S2 in addition to the light concentrating mirror 10. The auxiliary plate 90 has the same shape as the light concentrating mirror 10, and is arranged at a position symmetrical to the light concentrating mirror 10 with respect to the plane P. The sensors 9a, 9b are attached to the auxiliary plate 90. The sensors 9a, 9b monitor the plasma generation region AR or the vicinity thereof through the gas inlet port 33f.

In the present embodiment, in the second space S2, a partition wall 37 including an opening is provided between the gas supply port 6a and the light concentrating mirror 10. The partition wall 37 has a configuration similar to that of the partition wall 34 of the first embodiment, and is a constriction member that constricts the gas flow from the gas supply port 6a toward the gas main exhaust port 33b through the gas inlet port 33a.

As described above, in the present embodiment, the chamber 3 is formed symmetrical with respect to the plane P except for the partition wall 37. Other configuration of the chamber 3 is similar to that of the first embodiment.

### 3.2 Operation

The operation of the EUV light generation apparatus 2 according to the present embodiment is similar to that of the first embodiment except for the flow of the gas in the chamber 3. In the present embodiment, the gas supplied through the gas supply port 6a to the second space S2 in the chamber 3 mainly flows into the first space S1 through the gas inlet port 33a via the light concentrating mirror 10. Further, the gas supplied through the gas supply port 6b to the second space S2 in the chamber 3 mainly flows into the first space S1 through the gas inlet port 33f via the auxiliary plate 90. As described above, in the present embodiment, the flow of the gas in the chamber 3 is basically symmetric with respect to the plane P.

### 3.3 Effect

In the present embodiment, similarly to the first embodiment, since the gas passing through the opening 37a of the partition wall 37 is rectified and the flow velocity is improved, the entering and diffusion of debris from the opening 37a toward the external apparatus 100 is suppressed. Accordingly, entering of debris into the external apparatus 100 is suppressed. Therefore, according to the present embodiment, it is possible to suppress adhesion of debris to the light concentrating mirror 10 by the partition wall 33 as a debris shield, and it is possible to suppress entering of debris into the external apparatus 100 by the partition wall 37 as the constriction member. Further, since the flow of the gas in the chamber 3 is symmetrical with respect to the plane P, it is possible to suppress the target TG from being deviated from the plasma generation region AR due to the variation in the flow of the gas accompanied by plasma generation.

### 3.4 Modification

Next, various modifications of the second embodiment will be described. First and second modifications described below are different from the second embodiment only in the configuration of the constriction member.

### 3.4.1 First Modification

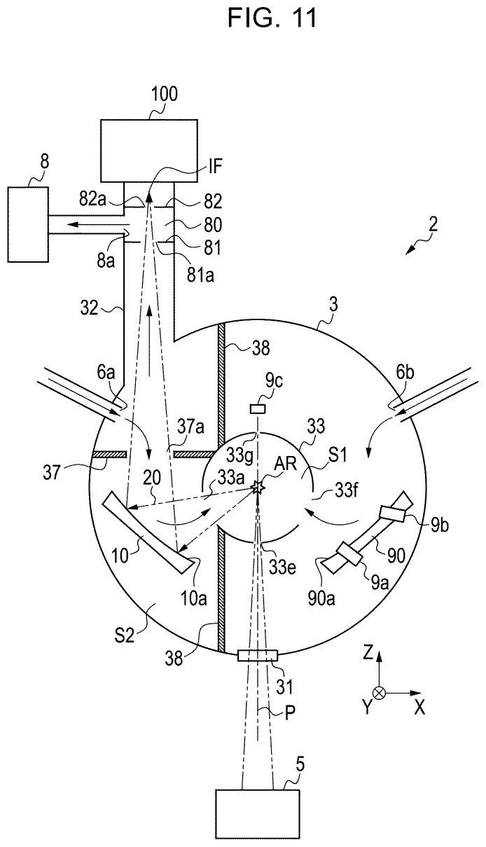

FIG. 11 schematically shows the configuration of the EUV light generation apparatus 2 according to the first modification of the second embodiment. The present modification is different from the second embodiment only in that a partition wall 38 is provided in addition to the partition wall 37. The partition wall 38 is provided in the second space S2 between the inner wall of the chamber 3 and the partition wall 33 so as to partition the region in which the gas supply port 6a and the gas inlet port 33a are formed and the region in which the gas supply port 6b and the gas inlet port 33f are formed. The partition wall 38 separates the gas flow supplied from the gas supply port 6a and the gas flow supplied from the gas supply port 6b.

In the present modification, since the partition wall 38 for separating the two gas flows supplied into the chamber 3 is provided, it is possible to suppress the effect of the gas flow from the gas supply port 6b on the region of the light concentrating mirror 10 side.

### 3.4.2 Second Modification

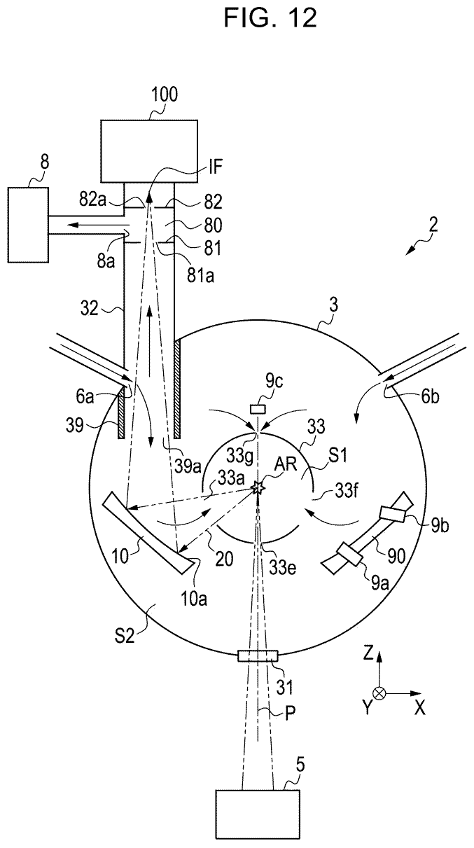

FIG. 12 schematically shows the configuration of the EUV light generation apparatus 2 according to the second modification of the second embodiment. In the present modification, a cylindrical structure 39 is provided instead of the partition wall 37. The cylindrical structure 39 has a configuration similar to the cylindrical structure 35 according to the first modification of the first embodiment. The cylindrical structure 39 is connected to an end portion of the connection pipe 32. Here, the cylindrical structure 39 may be integrally formed with the connection pipe 32.

The cylindrical structure 39 may be configured such that the cross-sectional area of the internal space thereof decreases as approaching the differential exhaust chamber 80.

Further, similarly to the second modification of the first embodiment, the constriction member may be formed of a block instead of the partition wall 37. The block may be configured of a plurality of members.

### 4. Electronic Device Manufacturing Method

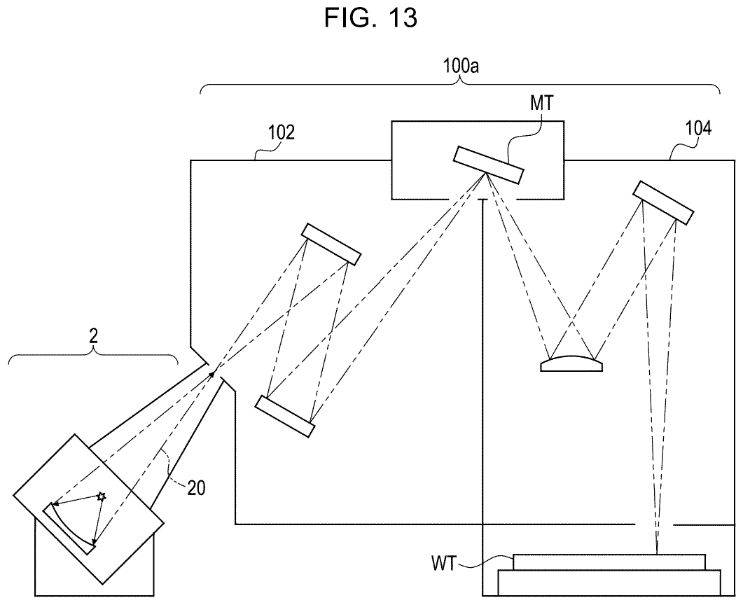

FIG. 13 schematically shows the configuration of the exposure apparatus 100a connected to the EUV light generation apparatus 2. In FIG. 13, the exposure apparatus 100a as the external apparatus 100 includes a mask irradiation unit 102 and a workpiece irradiation unit 104. The mask irradiation unit 102 irradiates a mask pattern on a mask table MT via a reflection optical system with the EUV light 20 incident from the EUV light generation apparatus 2. The workpiece irradiation unit 104 images the EUV light 20 reflected by the mask table MT onto a workpiece (not shown) placed on the workpiece table WT via a reflection optical system. The workpiece is a photosensitive substrate such as a semiconductor wafer on which photoresist is applied. The exposure apparatus 100a synchronously translates the mask table MT and the workpiece table WT to expose the workpiece to the EUV light 20 reflecting the mask pattern. Through the exposure process as described above, a device pattern is transferred onto the semiconductor wafer, thereby an electronic device can be manufactured.

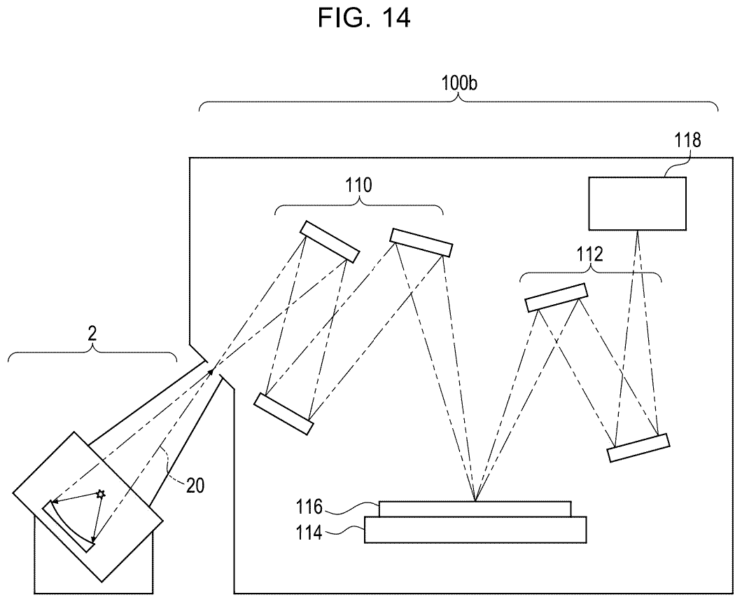

FIG. 14 schematically shows the configuration of the inspection apparatus 100b connected to the EUV light generation apparatus 2. In FIG. 14, the inspection apparatus 100b as the external apparatus 100 includes an illumination optical system 110 and a detection optical system 112. The EUV light generation apparatus 2 outputs, as a light source for inspection, EUV light 20 to the inspection apparatus 100b. The illumination optical system 110 reflects the EUV light 20 incident from the EUV light generation apparatus 2 to illuminate a mask 116 placed on a mask stage 114. Here, the mask 116 conceptually includes a mask blanks before a pattern is formed. The detection optical system 112 reflects the EUV light 20 from the illuminated mask 116 and forms an image on a light receiving surface of a detector 118. The detector 118 having received the EUV light 20 acquires an image of the mask 116. The detector 118 is, for example, a time delay integration (TDI) camera. Inspection for a defect of the mask 116 is performed based on the image of the mask 116 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 100a.

The description above is intended to be illustrative and the present disclosure is not limited thereto. Therefore, it would be obvious to those skilled in the art that various modifications to the embodiments of the present disclosure would be possible without departing from the spirit and the scope of the appended claims. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. An EUV light generation apparatus, comprising:
a chamber in which a target supplied to a plasma generation region inside thereof is irradiated with laser light to generate EUV light;
a light concentrating mirror arranged in the chamber and configured to reflect the EUV light toward an external apparatus;
a differential exhaust chamber arranged on an optical path of the EUV light reflected by the light concentrating mirror;
a gas supply port through which a gas is supplied to a space between the differential exhaust chamber and the light concentrating mirror;
a first partition wall arranged between the plasma generation region and the light concentrating mirror, the first partition wall being provided with a gas inlet port through which the gas supplied through the gas supply port flows into a side of the plasma generation region from a side of the light concentrating mirror and through which the EUV light traveling from the plasma generation region toward the light concentrating mirror passes;
a gas main exhaust port through which the gas flowing into the plasma generation region side from the light concentrating mirror side via the gas inlet port is exhausted; and
a constriction member arranged between the gas supply port and the light concentrating mirror and configured to allow the EUV light reflected by the light concentrating mirror to pass therethrough and constrict a gas flow from the gas supply port toward the gas inlet port.

2. The EUV light generation apparatus according to claim 1,
wherein the constriction member is a second partition wall including an opening through which the EUV light passes.

3. The EUV light generation apparatus according to claim 2,
wherein the second partition wall rectifies the gas flow at the opening and causes the gas to flow toward the light concentrating mirror.

4. The EUV light generation apparatus according to claim 2,
wherein the second partition wall intersects with an optical path of the EUV light, and partitions a region on the light concentrating mirror side and a region on the external apparatus side.

5. The EUV light generation apparatus according to claim 2,
wherein the opening has a shape similar to a cross-sectional shape of the EUV light at the second partition wall.

6. The EUV light generation apparatus according to claim 2,
wherein a size of the opening is larger than a size of a cross section of the EUV light at the second partition wall.

7. The EUV light generation apparatus according to claim 2,
wherein the differential exhaust chamber is a space sandwiched between a first orifice plate and a second orifice plate arranged closer to the external apparatus than the first orifice plate,
a first orifice arranged on the optical path of the EUV light is formed in the first orifice plate,
a second orifice arranged on the optical path of the EUV light is formed in the second orifice plate, and
the differential exhaust chamber is in communication with a gas exhaust port through which the gas is exhausted.

8. The EUV light generation apparatus according to claim 7, wherein a diameter of the first orifice is larger than a diameter of the second orifice.

9. The EUV light generation apparatus according to claim 8, wherein a diameter of the opening is larger than the diameter of the second orifice.

10. The EUV light generation apparatus according to claim 2,
wherein the second partition wall is arranged between the gas supply port and the light concentrating mirror on a side closer to the gas supply port than to the light concentrating mirror.

11. The EUV light generation apparatus according to claim 2,
wherein the second partition wall is arranged between the differential exhaust chamber and the light concentrating mirror on a side closer to the differential exhaust chamber than to the light concentrating mirror.

12. The EUV light generation apparatus according to claim 1,
wherein the constriction member is a cylindrical structure having an internal space through which the EUV light passes.

13. The EUV light generation apparatus according to claim 12,
wherein the gas supply port is arranged at a position through which the gas is supplied to the internal space of the cylindrical structure.

14. The EUV light generation apparatus according to claim 12,
wherein a cross-sectional area of the internal space of the cylindrical structure decreases along a travel direction of the EUV light.

15. The EUV light generation apparatus according to claim 1,
wherein the constriction member is a block which surrounds the optical path of the EUV light.

16. The EUV light generation apparatus according to claim 15, wherein the block is configured of a plurality of members.

17. An electronic device manufacturing method, comprising:
outputting EUV light generated by an EUV light generation apparatus to an exposure apparatus; and
exposing a photosensitive substrate to the EUV light in the exposure apparatus to manufacture an electronic device,
the EUV light generation apparatus including:
a chamber in which a target supplied to a plasma generation region inside thereof is irradiated with laser light to generate the EUV light;
a light concentrating mirror arranged in the chamber and configured to reflect the EUV light toward an external apparatus;
a differential exhaust chamber arranged on an optical path of the EUV light reflected by the light concentrating mirror;
a gas supply port through which a gas is supplied to a space between the differential exhaust chamber and the light concentrating mirror;
a first partition wall arranged between the plasma generation region and the light concentrating mirror, the first partition wall being provided with a gas inlet port through which the gas supplied through the gas supply port flows into a side of the plasma generation region from a side of the light concentrating mirror and through which the EUV light traveling from the plasma generation region toward the light concentrating mirror passes;
a gas main exhaust port through which the gas flowing into the plasma generation region side from the light concentrating mirror side via the gas inlet port is exhausted; and
a constriction member arranged between the gas supply port and the light concentrating mirror and configured to allow the EUV light reflected by the light concentrating mirror to pass therethrough and constrict a gas flow from the gas supply port toward the gas inlet port.

18. An electronic device manufacturing method, comprising:
inspecting a defect of a mask by irradiating the mask with EUV light generated by an EUV light generation apparatus;
selecting a mask using a result of the inspection; and
exposing and transferring a pattern formed on the selected mask onto a photosensitive substrate,
the EUV light generation apparatus including:
a chamber in which a target supplied to a plasma generation region inside thereof is irradiated with laser light to generate the EUV light;
a light concentrating mirror arranged in the chamber and configured to reflect the EUV light toward an external apparatus;
a differential exhaust chamber arranged on an optical path of the EUV light reflected by the light concentrating mirror;
a gas supply port through which a gas is supplied to a space between the differential exhaust chamber and the light concentrating mirror;
a first partition wall arranged between the plasma generation region and the light concentrating mirror, the first partition wall being provided with a gas inlet port through which the gas supplied through the gas supply port flows into a side of the plasma generation region from a side of the light concentrating mirror and through which the EUV light traveling from the plasma generation region toward the light concentrating mirror passes;
a gas main exhaust port through which the gas flowing into the plasma generation region side from the light concentrating mirror side via the gas inlet port is exhausted; and
a constriction member arranged between the gas supply port and the light concentrating mirror and configured to allow the EUV light reflected by the light concentrating mirror to pass therethrough and constrict a gas flow from the gas supply port toward the gas inlet port.
